(19) United States
(12) Patent Application Publication
(10) Pub. No.: US 2016/0358696 A1
(43) Pub. Date: Dec. 8, 2016

(54) NOISE SHIELD CABLE

(71) Applicant: HITACHI METALS, LTD., TOKYO (JP)

(72) Inventors: YOSUKE SUMI, HITACHINAKA (JP); KATSUTOSHI NAKATANI, HITACHI (JP); KATSUYA AKIMOTO, HITACHI (JP); KENJI AJIMA, HITACHIOTA (JP); HIROSHI OKIKAWA, HITACHI (JP)

(21) Appl. No.: 15/167,660

(22) Filed: May 27, 2016

(30) Foreign Application Priority Data
Jun. 2, 2015 (JP) 2015-112488

(51) Int. Cl. H01B 11/18; H05K 9/00

(52) U.S. Cl. CPC H01B 11/1895; H05K 9/0075

(57) ABSTRACT

A noise shield cable includes an electrically insulated wire including a conductor wire coated with an insulator around a circumference thereof, and a magnetic tape layer including a magnetic tape wound around an outer circumference of the electrically insulated wire at least twice in such a manner as to include a region comprising three or more overlapped layers. A first outermost layer and a second outermost layer of that region are being joined together therebetween by resistance welding.

The present application is based on Japanese patent application No. 2015-112488 filed on Jun. 2, 2015, the entire contents of which are incorporated herein by reference.

### BACKGROUND OF THE INVENTION

1. Field of the Invention

This invention relates to a noise shield cable using a magnetic tape to suppress common mode noise.

2. Description of the Related Art

Conventionally, a noise shield cable has been suggested, that is produced by winding a magnetic tape around an electric wire, with no ferrite core being mounted around the cable. (Refer to JP-A-2002-25356, for example.)

This noise shield cable is designed in such a manner that a magnetic metal tape (also known as a magnetic tape) of a predetermined width is wound around outer circumferences of an electrically insulated wire consisting of a conductor wire coated with an insulator therearound, at a predetermined pitch in a cable longitudinal direction. With the conventional noise shield cable, the noise suppression effect is controlled according to the tape length and the tape width. Further, by reducing the tape width of the magnetic tape, dividing into a plurality of blocks, and arranging at a suitable pitch, the flexibility of the cable is enhanced.

### SUMMARY OF THE INVENTION

However, although the conventional noise shield cable uses the magnetic tape for the suppression of common mode noise, the magnetic tape is generally fixed by winding the magnetic tape on the outer circumferences of the electrically insulated wires, subsequently overlapping ends of the magnetic tape together, and fixing the overlapped portions with an adhesive tape, or overlapping ends of the magnetic tape together, and fixing a plurality of areas in the cable longitudinal direction of the overlapped portions by a resistance welding.

In the method by fixing the magnetic tape with the adhesive tape, the adhesive tape is likely to peel off, or the contact between the ends of the magnetic tape is likely to be insufficient. Also, in the method by fixing the plurality of areas in the cable longitudinal direction by the resistance welding, because lowering in the magnetic permeability of the resistance welded portions narrows a region where the magnetic path is closed, the noise suppression effect is likely to lower.

Accordingly, it is an object of the present invention to provide a noise shield cable capable of achieving a desired suppression effect for common mode noise.

According to an aspect of an embodiment of the invention, a noise shield cable comprises:

an electrically insulated wire comprising a conductor wire coated with an insulator around a circumference thereof; and

a magnetic tape layer comprising a magnetic tape wound around an outer circumference of the electrically insulated wire at least twice in such a manner as to include a region comprising three or more overlapped layers, a first outermost layer and a second outermost layer of that region being joined together therebetween by resistance welding.

In the embodiment, the following modifications and changes may be made.

(i) A multiplicity of the magnetic tape layers are formed at a predetermined pitch in a cable longitudinal direction.

(ii) A joining portion of the magnetic tape joined by resistance welding has a maximum length in the cable longitudinal direction of not greater than ⅓ a width of the magnetic tape.

(Points of the Invention)

The present invention allows for achieving a desired suppression effect for common mode noise.

### BRIEF DESCRIPTION OF THE DRAWINGS

The preferred embodiments according to the invention will be explained below referring to the drawings, wherein:

FIG. 1 is a front view showing a schematic configuration of a noise shield cable in an exemplary embodiment of the present invention;

FIG. 2 is a transverse cross sectional view showing the noise shield cable shown in FIG. 1;

FIG. 3A is a view showing only a magnetic tape layer of the noise shield cable shown in FIG. 1 viewed in a cable longitudinal direction;

FIG. 3B is a front view showing only the magnetic tape layer of the noise shield cable shown in FIG. 1;

FIG. 4A is a front view showing a modification to the magnetic tape layer;

FIG. 4B is a front view showing a modification to the magnetic tape layer;

FIG. 4C is a front view showing a modification to the magnetic tape layers;

FIG. 4D is a front view showing a modification to the magnetic tape layer; and

FIG. 4E is a front view showing a modification to the magnetic tape layer.

### DETAILED DESCRIPTION OF THE PREFERRED EMBODIMENTS

Below will be described an exemplary embodiment of the present invention, in conjunction with the accompanying drawings. Note that throughout the drawings, elements having substantially the same functions will be given the same reference numerals, and duplicated descriptions thereof will be omitted.

### Embodiment

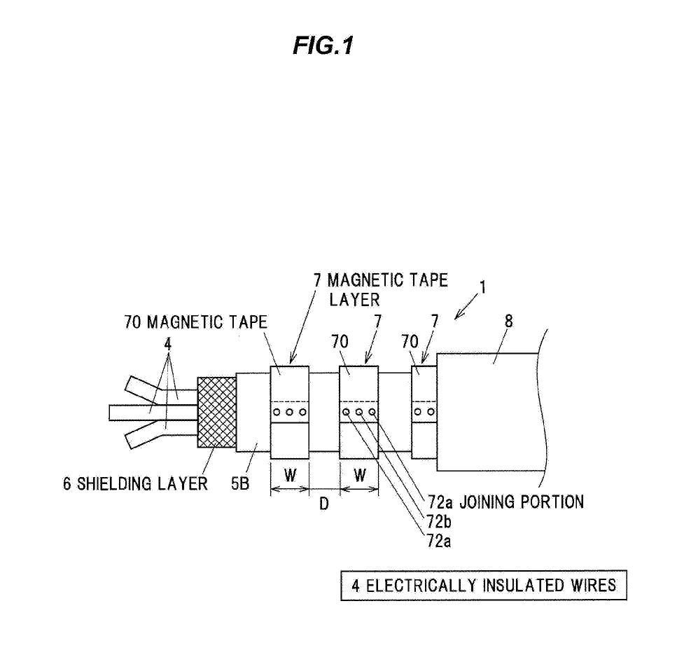

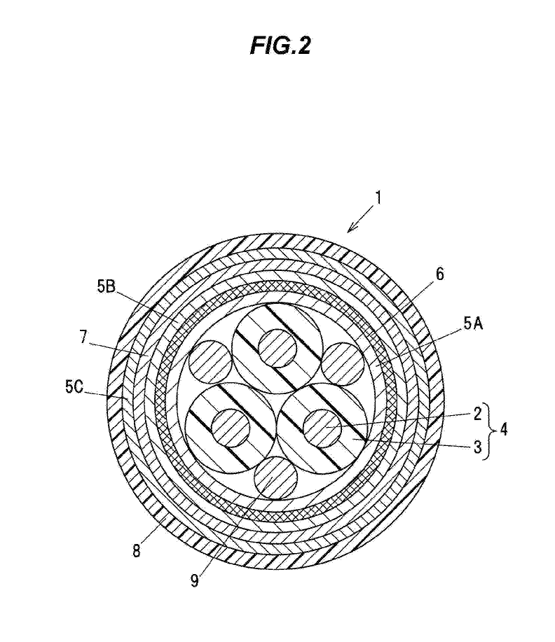

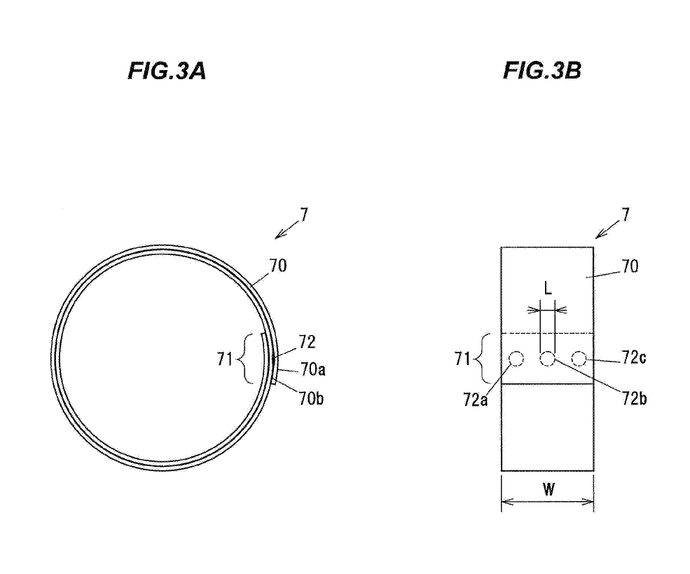

FIG. 1 is a front view showing a schematic configuration of a cable 1 with a noise shield in the exemplary embodiment of the present invention. FIG. 2 is a transverse cross sectional view showing the cable 1 with the noise shield shown in FIG. 1. FIG. 3A is a view showing only a magnetic tape layer 7 of the cable 1 with the noise shield shown in FIG. 1 viewed in a cable longitudinal direction, and FIG. 3B is a front view showing only that magnetic tape layer 7 of FIG. 3A. Note that in FIG. 1, no inclusions 9 are shown.

This cable 1 with a noise shield is composed of a multiplicity of (in this exemplary embodiment, three) electrically insulated wires 4 each consisting of a respective conductor wire 2 coated with a respective insulator 3 over a circumference thereof, a resin tape layer 5A, which is formed of a resin tape wrapped around those multiple electrically insulated wires 4 and inclusions 9 each interposed between adjacent electrically insulated wires 4, a shielding layer 6, which is provided over an outer circumference of the resin tape layer 5A, a resin tape layer 5B, which is provided over an outer circumference of the shielding layer 6, a multiplicity of magnetic tape layers 7 of a predetermined width W, which are formed around outer circumferences, respectively, of the resin tape layer 5B at a predetermined pitch D in the cable longitudinal direction, a resin tape layer 5C, which is provided over an outer circumference of those multiple magnetic tape layers 7 and the resin tape layer 5B, and a sheath 8, which is configured as an insulating protective layer made of a resin or the like.

The electrically insulated wires 4 are designed to transmit electric power or signals of frequencies of 100 kHz to 1 MHz, for example. Note that although the number of the electrically insulated wires 4 is multiple in this exemplary embodiment, it may be one. In addition, the electrically insulated wires 4 may be twisted pair wires for differential signaling.

The resin tape layer 5A is formed by interposing the inclusions 9 each between adjacent electrically insulated wires 4, and wrapping a resin tape around an outer circumference of the multiple electrically insulated wires 4 and the inclusions 9 over the cable length. The resin tape layer 5B is formed by wrapping a resin tape around the outer circumference of the shielding layer 6 over the cable length. The resin tape layer 5C is formed by wrapping a resin tape around the outer circumference of the resin tape layer 5B and the magnetic tape layers 7 over the cable length. The resin tapes for the resin tape layers 5A, 5B, and 5C may use, for example, a tape made of a resin such as polyethylene terephthalate (PET), polypropylene based resin, or the like.

The shielding layer 6 is formed by conductive wire braiding, for example, and is connected to ground. Incidentally, the shielding layer 6 may be a wrapped tape with a conductor.

(Configuration of the Magnetic Tape Layers 7)

The magnetic tape layers 7 are each formed by winding a magnetic tape 70 of a width W around an outer circumference of the resin tape layer 5B at least twice in such a manner as to include a region 71 comprising three or more overlapped layers, and resistance welding joining between the first outermost layer 70a and the second outermost layer 70b at that region 71. Joining portions 72a, 72b, and 72c (also referred to collectively as “joining portions 72”) of the magnetic tape 70 to be joined by resistance welding are formed in the cable longitudinal direction (i.e. the tape width direction), for example. The width W of the magnetic tape 70 is preferably e.g. 5 to 50 mm. The pitch D between the magnetic tape layers 7 is preferably e.g. 5 to 50 mm. Note that in FIG. 3B, the reference character L is the length in the cable longitudinal direction of one joining portion 72.

Note that the joining portions 72 may have a maximum length in the cable longitudinal direction (i.e. the tape width direction) of not greater than ⅓ or not greater than ⅕ the width (i.e. the length in the cable longitudinal direction) W of the magnetic tape 70. The maximum length in the cable longitudinal direction of the joining portions 72 refers to a total length of a largest number of the joining portions 72 present in the same cross section in the cable longitudinal direction through the joining portions 72 of the magnetic tape 70. In the case shown in FIGS. 1, 3A and 3B, the maximum length in the cable longitudinal direction of the joining portions 72 is 3L, the total length of the three joining portions 72.

To suppress common mode noise, it is preferable that the magnetic material for constituting the magnetic tape 70 is made of a soft magnetic material, which has a small coercive force and a high magnetic permeability. As the soft magnetic material, it is possible to use, for example, an amorphous alloy such as a cobalt (Co) base amorphous alloy, an iron (Fe) base amorphous alloy or the like, a ferrite such as a manganese-zinc (Mn—Zn) based ferrite, a nickel-zinc (Ni—Zn) based ferrite, a nickel-zinc-copper (Ni—Zn—Cu) based ferrite or the like, or a soft magnetic metal such as an iron-nickel (Fe—Ni) based alloy (permalloy), an iron-silicon-aluminum (Fe—Si—Al) based alloy (sendust), an iron-silicon (Fe—Si) based alloy (silicon steel) or the like.

(Method for Forming the Magnetic Tape Layers 7)

The magnetic tape 70 may be e.g. a 10 to 25 μm thick and 30 mm wide magnetic material. The magnetic tape 70 is wound around the outer circumference of the resin tape layer 5B at least twice in such a manner as to include the region 71 comprising the three or more overlapped layers, and the first outermost layer 70a and the second outermost layer 70b at that region 71 are joined together therebetween by resistance welding. In the case shown in FIGS. 1 and 3B, the three joining portions 72a, 72b, and 72c aligned in the cable longitudinal direction are joined by resistance welding. For example, a positive electrode is brought into contact with a surface (an opposite surface to the resin tape 5B side) corresponding to the middle joining portion 72b of the region 71 comprising the three or more overlapped layers, while negative electrodes are brought into contact with surfaces (opposite surfaces to the resin tape 5B side) corresponding to the joining portions 72a and 72c on both sides, respectively, of that region 71, and a current is passed between the positive electrode and the negative electrodes, thereby resulting in resistance welding of the three joining portions 72a, 72b, and 72c.

(Functions and Advantageous Effects of the Embodiment)

The above described embodiment has the following functions and advantageous effects.

(1) Common mode noise is suppressed by the magnetic tape layers 7.

(2) Since the joining portions 72 of the magnetic tape 70 joined by resistance welding are formed between the first outermost layer 70a and the second outermost layer 70b of the region 71 comprising the three or more overlapped layers by winding the magnetic tape 70 at least twice, as compared with the method by resistance welding fixing a plurality of areas in the cable longitudinal direction of portions overlapped by winding substantially once, a region where the magnetic permeability is lowered by the resistance welding is small, and a region where the magnetic path is closed is wide, therefore allowing for achieving a desired suppression effect for common mode noise.

(3) Since the magnetic tape layers 7 of the predetermined width are provided at the predetermined pitch in the cable longitudinal direction, as compared with when a magnetic tape layer is provided over the entire cable length, the same suppression effect for common mode noise can be achieved, while the superior flexibility can be achieved.

(4) Since no ferrite core is used, the product is aesthetically superior, there are no handling problems such as ferrite core cracking, etc., there is no increase in the outer diameter of the cable, and it is possible to suppress the radiation of common mode noise.

(Modifications)

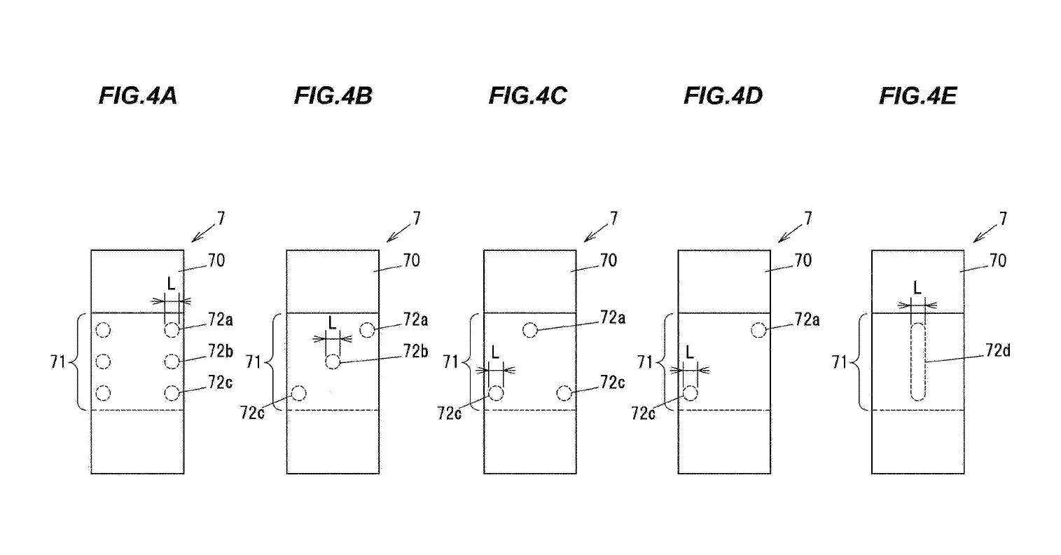

FIGS. 4A to 4E show modifications to the magnetic tape layers 7. The modifications shown in FIGS. 4A to 4E are the same as the above embodiment in that the magnetic tape 70 is wound two or more times, but differ from the above embodiment in arrangements of the joining portions 72. The joining portions 72 in the modifications are designed to have a maximum length in the cable longitudinal direction (i.e. the tape width direction) of not greater than ⅓, or not greater than ⅕ the width (i.e. the length in the cable longitudinal direction) W of the magnetic tape 70.

The modification shown in FIG. 4A is configured in such a manner that the three joining portions 72a, 72b, and 72c are each arranged in the cable circumferential direction at both left and right sides of the width of the magnetic tape 70. In this case, the maximum length in the cable longitudinal direction of the joining portions 72 is 2L where L is the length of one joining portion 72.

The modification shown in FIG. 4B is configured in such a manner that the three joining portions 72a, 72b, and 72c are arranged obliquely to the cable longitudinal direction. In this case, the maximum length in the cable longitudinal direction of the joining portions 72 is 1L where L is the length of one joining portion 72.

The modification shown in FIG. 4C is configured in such a manner that the three joining portions 72a, 72b, and 72c are staggered (arranged in a zigzag). In this case, the maximum length in the cable longitudinal direction of the joining portions 72 is 2L where L is the length of one joining portion 72.

The modification shown in FIG. 4D is configured in such a manner that the two joining portions 72a and 72c are arranged obliquely to the cable longitudinal direction. In this case, the maximum length in the cable longitudinal direction of the joining portions 72 is 1L where L is the length of one joining portion 72.

The modification shown in FIG. 4E is configured in such a manner that one joining portion 72d, which is short in the cable longitudinal direction and long in the cable circumferential direction, is disposed. In this case, a positive or negative electrode of a shape corresponding to that joining portion 72d may be used. In this case, the maximum length in the cable longitudinal direction of the joining portions 72 is 1L where L is the length in the cable longitudinal direction of that joining portion 72d. Note that one joining portion 72d and another joining portion 72d, which is long in the cable circumferential direction, may be arranged at both left and right sides, respectively, of the width of the magnetic tape 70.

With the modifications shown in FIGS. 4A to 4E, even when the joining portions 72 are formed between the second outermost layer 70b and the third outermost layer as well as between the first outermost layer 70a and the second outermost layer 70b of the magnetic tape 70, since the joining portions 72 of the magnetic tape 70 joined by resistance welding have the maximum length in the cable longitudinal direction of not greater than ⅓ or not greater than ⅕ the width W of the magnetic tape, as compared with the method by resistance welding fixing a plurality of areas in the cable longitudinal direction, a region where the magnetic permeability is lowered by the resistance welding is small, and a region where the magnetic path is closed is wide, therefore allowing for achieving a desired suppression effect for common mode noise.

Note that the invention is not limited to the above exemplary embodiments, but various embodiments are possible. For example, although in the present exemplary embodiments, the multiplicity of magnetic tape layers 7 are provided, there may be provided one magnetic tape layer. That one magnetic tape layer 7 may be 5 to 50 mm in width, and may be formed continuously in the cable longitudinal direction.

Further, it is possible to omit or alter some of the elements of the above described exemplary embodiments without altering the spirit of the invention. For example, if there is no problem in terms of winding the resin tape around the multiplicity of electrically insulated wires 4, the inclusions 9 may be omitted. Further, the resin tape layer 5C formed over the outer sides of the magnetic tape layers 7 may be omitted.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A noise shield cable, comprising:
an electrically insulated wire comprising a conductor wire coated with an insulator around a circumference thereof; and
a magnetic tape layer comprising a magnetic tape wound around an outer circumference of the electrically insulated wire at least twice in such a manner as to include a region comprising three or more overlapped layers, a first outermost layer and a second outermost layer of that region being joined together therebetween by resistance welding.

2. The noise shield cable according to claim 1, wherein a multiplicity of the magnetic tape layers are formed at a predetermined pitch in a cable longitudinal direction.

3. The noise shield cable according to claim 1, wherein a joining portion of the magnetic tape joined by resistance welding has a maximum length in the cable longitudinal direction of not greater than ⅓ a width of the magnetic tape.
